(19) United States
(12) Patent Application Publication
(10) Pub. No.: US 2008/0315950 A1
(43) Pub. Date: Dec. 25, 2008

(54) Integrated Circuit Amplifiers Having Switch Circuits Therein that Provide Reduced 1/f Noise

(75) Inventors: Jeongwook Koh, Seoul (KR); Chun-Deok Suh, Gyeonggi-do (KR); Eun-Chul Park, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/203,260

(22) Filed: Sep. 3, 2008

(30) Foreign Application Priority Data
Jun. 6, 2007 (KR) 2007-90613

(51) Int. Cl. H03F 3/45; H03L 7/00

(52) U.S. Cl. 330/253; 327/144; 330/277

(57) ABSTRACT

Integrated circuit devices include a pair of field effect transistors having shared source terminals, shared drain terminals and shared gate terminals, which may be treated herein as being electrically coupled in parallel. A switch circuit is also provided, which is configured to drive a body terminal of a first one of the pair of field effect transistors with an alternating sequence of first and second unequal body voltages. This alternating sequence is synchronized with a first clock signal. The switch circuit is also configured to drive a body terminal of a second one of the pair of field effect transistors with an alternating sequence of third and fourth unequal body voltages, which is synchronized with a second clock signal. The first and third body voltages may have equivalent magnitudes and the second and fourth body voltages may have equivalent magnitudes. The first and second clock signals may have 50% duty cycles and may be 180 degrees out-of-phase relative to each other.

### REFERENCE TO PRIORITY APPLICATION

This U.S. non-provisional patent application claims priority under 35 U.S.C. § 119 to Korean Patent Application No. 10-2007-0090613, filed Sep. 6, 2007, the entire contents of which are hereby incorporated herein by reference.

### FIELD OF THE INVENTION

The present invention relates to integrated circuit devices and, more particularly, to integrated circuit amplifiers and methods of operating same.

### BACKGROUND OF THE INVENTION

In comparison with bipolar or GaAs semiconductor circuits, radio frequency (RF) CMOS circuits may have high 1/f noise (i.e., a low-frequency noise), which is dominant in the frequency domain unlike thermal noise. Also, the down-scaling of CMOS circuits may further degrade the 1/f noise characteristics of CMOS circuits. The down-scaling of CMOS circuits reduces a supply voltage and is advantageous in terms of power amplification. However, the degradation of the 1/f noise characteristics of CMOS circuits further worsens a signal-to-noise ratio (SNR) of CMOS communication semiconductor circuits. Therefore, a communication semiconductor device using a CMOS circuit may have reduce sensitivity, thus degrading the receive (RX) sensitivity of the communication semiconductor device. If a CMOS direct conversion receiver is implemented in a narrowband communication system, such as the Global System for Mobile Communications (GSM), the 1/f noise may become the main noise source of up to several hundreds of kH through several tens of MHz.

### SUMMARY OF INVENTION

Integrated circuit devices according to some embodiments of the present invention include a pair of field effect transistors having shared source terminals, shared drain terminals and shared gate terminals, which may be treated herein as being electrically coupled in parallel. A switch circuit is also provided. The switch circuit is configured to drive a body terminal of a first one of the pair of field effect transistors with an alternating sequence of first and second unequal body voltages. This alternating sequence is synchronized with a first clock signal. The switch circuit is also configured to drive a body terminal of a second one of the pair of field effect transistors with an alternating sequence of third and fourth unequal body voltages, which is synchronized with a second clock signal. The first and third body voltages may have equivalent magnitudes and the second and fourth body voltages may have equivalent magnitudes. In addition, the first and second clock signals may be synchronized with each other. The first and second clock signals may have 50% duty cycles and may be 180 degrees out-of-phase relative to each other.

Additional embodiments of the present invention include a differential amplifier having first and second pairs of field effect transistors and first and second switch circuits. The first pair of field effect transistors have shared first source terminals, shared first drain terminals and shared first gate terminals. The shared first gate terminals are electrically connected to a first input of the differential amplifier. The shared second pair of field effect transistors have shared second source terminals, shared second drain terminals and shared second gate terminals. The shared second gate terminals are electrically connected to a second input of the differential amplifier. The first switch circuit is configured to drive a body terminal of a first one of the first pair of field effect transistors with an alternating sequence of first and second unequal body voltages that is synchronized with a first clock signal. This first switch circuit may also be configured to drive a body terminal of a second one of the first pair of field effect transistors with an alternating sequence of third and fourth unequal body voltages that is synchronized with a second clock signal. Similarly, the second switch circuit is configured to drive a body terminal of a first one of the second pair of field effect transistors with the alternating sequence of the first and second unequal body voltages, and may be further configured to drive a body terminal of a second one of the second pair of field effect transistors with the alternating sequence of third and fourth unequal body voltages.

The differential amplifier according to embodiments of the invention may also include an output circuit, which is electrically coupled to the shared first drain terminals and the shared second drain terminals, and a current mirror circuit, which is electrically coupled to the shared first source terminals and the shared second source terminals.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a circuit diagram of a CMOS amplifier according to an exemplary embodiment of the present invention;

FIG. 2 is a timing diagram illustrating the waveforms of clock signals illustrated in FIG. 1;

FIG. 3 is a graph showing the relationship between a body bias voltage and a threshold voltage of a first transistor and a second transistor illustrated in FIG. 1;

FIG. 4 is a circuit diagram of a CMOS amplifier according to another exemplary embodiment of the present invention;

FIG. 5 is a frequency versus noise graph of the CMOS amplifier illustrated in FIG. 4;

FIGS. 6A and 6B are graphs showing an input signal and an output signal of the CMOS amplifier illustrated in FIG. 4; and

FIG. 7 is a time versus amplitude graph of the CMOS amplifier illustrated in FIG. 4.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

A complementary metal oxide semiconductor (CMOS) amplifier according to the present invention can reduce 1/f noise (i.e., a low-frequency noise) by using two field-effect transistors (FETs) connected in parallel. The CMOS amplifier according to the present invention includes: a first transistor including a first source, a first gate, a first drain, and a first body; a second transistor including a second source, a second gate, a second drain, and a second body; a source terminal connecting the first source and the second source in common; a drain terminal connecting the first drain and the second drain in common; a gate terminal connecting the first gate and the second gate in common; a first switch connecting one of a first body voltage and a second body voltage to the first body according to a first clock; and a second switch connecting one of the first body voltage and the second body voltage to the second body according to a second clock.

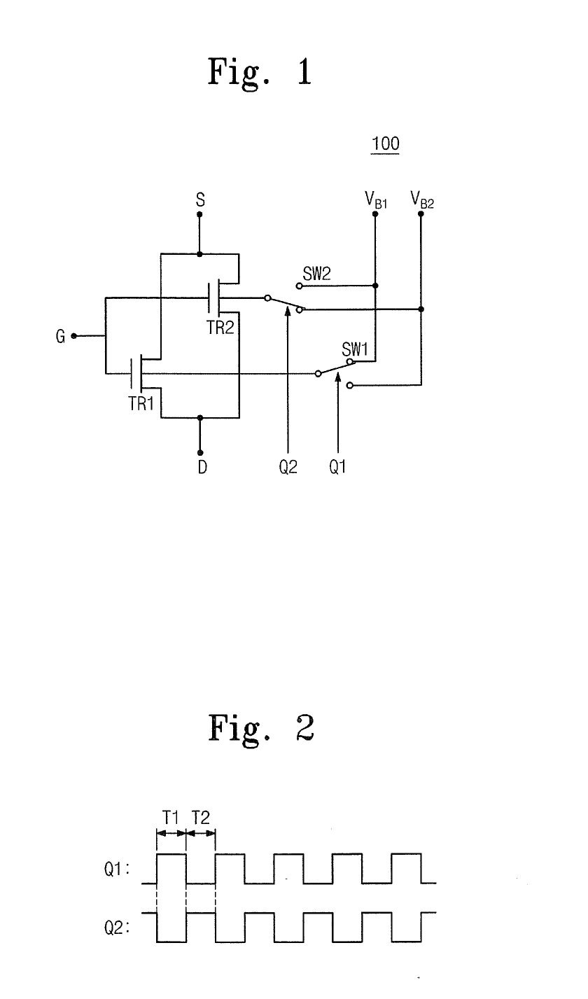

The CMOS amplifier according to an embodiment of the present invention drives a first transistor and a second transistor alternately in synchronization with a first clock and a second clock, thereby reducing power consumption and 1/f noise. Also, the CMOS amplifier according to the present invention is applied to continuous signal processing. FIG. 1 is a circuit diagram of a CMOS amplifier according to an exemplary embodiment of the present invention. FIG. 2 is a timing diagram illustrating the waveforms of clock signals illustrated in FIG. 1. Referring to FIG. 1, a CMOS amplifier 100 according to an exemplary embodiment of the present invention includes a first transistor TR1, a second transistor TR2, a first switch SW1, and a second switch SW2. The first transistor TR1 includes a first source, a first gate, a first drain, and a first body, and the second transistor TR2 includes a second source, a second gate, a second drain, and a second body. A source terminal S connects the first source and the second source in common, a drain terminal D connects the first drain and the second drain in common, and a gate terminal G connects the first gate and the second gate in common.

The first switch SW1 connects one of a first body voltage B1 and a second body voltage B2 to the first body according to the voltage level of a first clock Q1, and the second switch SW2 connects one of the first body voltage B1 and the second body voltage B2 to the second body according to the voltage level a second clock Q2. The first transistor TR1 and the second transistor TR2 are physically identical. The first transistor TR1 and the second transistor TR2 may be implemented using FETs. Also, the first switch SW1 and the second switch SW2 may be implemented using small-sized MOS switches.

Referring to FIG. 2, during a period T1, the first clock Q1 has a high state and the second clock Q2 has a low state. During a period T2, the first clock Q1 has the low state and the second clock Q2 has the high state. That is, the first clock Q1 and the second clock Q2 have the opposite state values. That is, the first clock Q1 and the second clock Q2 are clocks that switch in the full range of a supply voltage—ground voltage (VDD−VSS) that have a 50% duty cycle and the opposite phases.

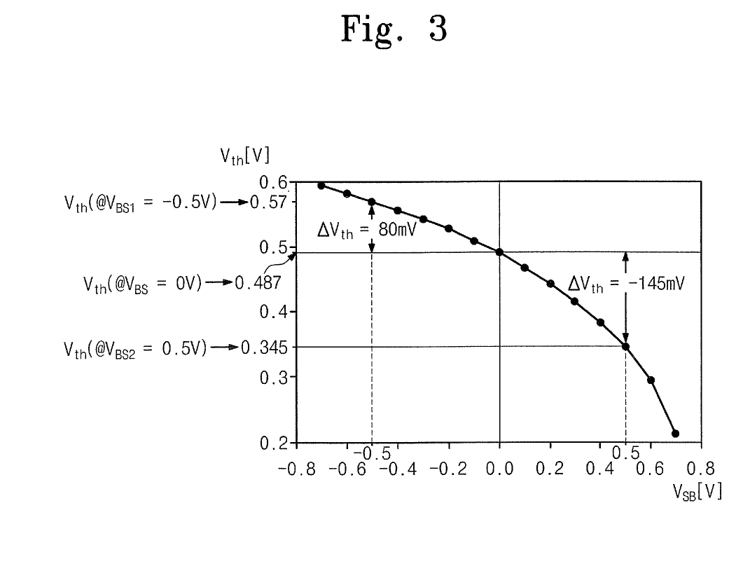

FIG. 3 is a graph showing the relationship between a body bias voltage V_{SB} and a threshold voltage Vₜₕ of the first transistor TR1 and the second transistor TR2 illustrated in FIG. 1. Equation (1) shows a change in the threshold voltage Vₜₕ depending on a change in the body bias voltage V_{SB}. That is, the graph of FIG. 3 shows that the threshold voltage Vₜₕ changes with a change in the body bias voltage V_{SB} according to Equation (1).

ΔVₜₕ=γ(\sqrt{2|φ_{F}|−V_{SB}}−\sqrt{2|φ_{F}|}) (1)

where ΔVₜₕ denotes a variation in a threshold voltage, γ denotes a constant value according to a doping concentration and the SiO₂ thickness of a gate terminal, φ_{F} denotes the Fermi level, and V_{SB} denotes the bias voltage of a substrate of a transistor. This equation (1) is disclosed in a textbook by Y. J. Park, entitled “VLSI Device Theory,” Kyohak Publishing Co., Ltd., p. 300 (1995) and a textbook by B. Streetman, entitled “Solid State Electronic Design 3^{rd} Edition”, Prentice-Hall, p. 321.

Referring to FIGS. 1 through 3, when the body bias voltage V_{SB} is 0 V, the threshold voltage of the first transistor TR1 and the second transistor TR2 is 0.487 V. According to an embodiment of the present invention, the first body voltage B1 is set to −0.5 V and the second body voltage B2 is set to 0.5 V. When the first body voltage B1 is connected to the body of the first transistor TR1, the threshold voltage of the first transistor TR1 is 0.57 V. Also, when the second body voltage B2 is connected to the body of the first transistor TR1, the threshold voltage of the first transistor TR1 is 0.345 V. The second transistor TR2 may be physically identical to the first transistor TR1. Therefore, a change in the threshold voltage of the second transistor TR2 depending on the first and second body voltages may be identical to the change in the threshold voltage of the first transistor TR1 depending on the first and second body voltages.

Referring to FIGS. 1 through 3, the CMOS amplifier according to an embodiment of the present invention supplies a supply voltage to the source terminal S, applies an input signal to the gate terminal G, and outputs an output signal from the drain terminal D. During the period T1, the first clock Q1 has a high state and the second clock Q2 has a low state. That is, when the first clock Q1 is in the high state, the first switch SW1 connects the first body voltage B1 to the body of the first transistor TR1 and the second switch SW2 connects the second body voltage B2 to the body of the second transistor TR2. That is, when the first clock Q1 is in the high state, the first body voltage B1 is applied to the body of the first transistor TR1 and the second body voltage B2 is applied to the body of the second transistor TR2. In this case, the threshold voltage of the first transistor TR1 is 0.57 V and the threshold voltage of the second transistor TR2 is 0.345 V. At this point, an input signal is applied from the gate terminal G. The voltage level of the input signal is set to about 0.345˜0.57 V, which means the first transistor TR1 is turned off and the second transistor TR2 is turned on. Thus, a signal input from the gate terminal G is output through the second transistor TR2 to the drain terminal D.

During the period T2, the first clock Q1 has a low state and the second clock Q2 has a high state. Thus, when the first clock Q1 is in the low state, the first switch SW1 connects the second body voltage B2 to the body of the first transistor TR1 and the second switch SW2 connects the first body voltage B1 to the body of the second transistor TR2. When the first clock Q1 is in the low state, the second body voltage B2 is applied to the body of the first transistor TR1 and the first body voltage B1 is applied to the body of the second transistor TR2. In this case, the threshold voltage of the first transistor TR1 is 0.345 V and the threshold voltage of the second transistor TR2 is 0.57 V. At this point, an input signal is applied from the gate terminal G. The voltage level of the input signal is set to about 0.345 ˜0.57 V, which means the first transistor TR1 is turned on and the second transistor TR2 is turned off. Thus, a signal input from the gate terminal G is output through the first transistor TR1 to the drain terminal D.

If the period T1 plus the period T2 is a cycle T, a current flowing through the drain terminal D during the cycle T is I_{D}. If a current flowing through an FET during the cycle T is I_{D}, the power of the FET is proportional to I_{D}². On the other hand, in the case of the CMOS amplifier according to embodiments of the present invention, a current flowing during the half cycle (T1 or T2) is 0.5I_{D} and thus a current flowing during the cycle T is I_{D} (i.e., 0.5I_{D}×2). Also, the power of the CMOS amplifier according to the present invention is proportional to 0.5I_{D}²(i.e., 0.25I_{D}²+0.25I_{D}²), which is the sum of the square of a current flowing during the first half cycle T1 and the square of a current flowing during the second half cycle T2.

Because the 1/f noise (i.e., a low-frequency noise) increases in proportion to the power used, a CMOS amplifier according to an embodiment of the present invention may consume about half the power in comparison with the case of using only one FET. Thus, the CMOS amplifier may reduce the 1/f noise by about ½ in comparison with the case of using only one FET. Also, the CMOS amplifier according to the illustrated embodiment enables the transistor to operate continuously. Thus, the CMOS amplifier according to the illustrated embodiments illustrated can be applied to continuous signal processing. For example, the embodiments of the invention can be used to improve the receive (RX) sensitivities of an audio system and a CMOS direct conversion receiver in the Global System for Mobile Communications (GSM).

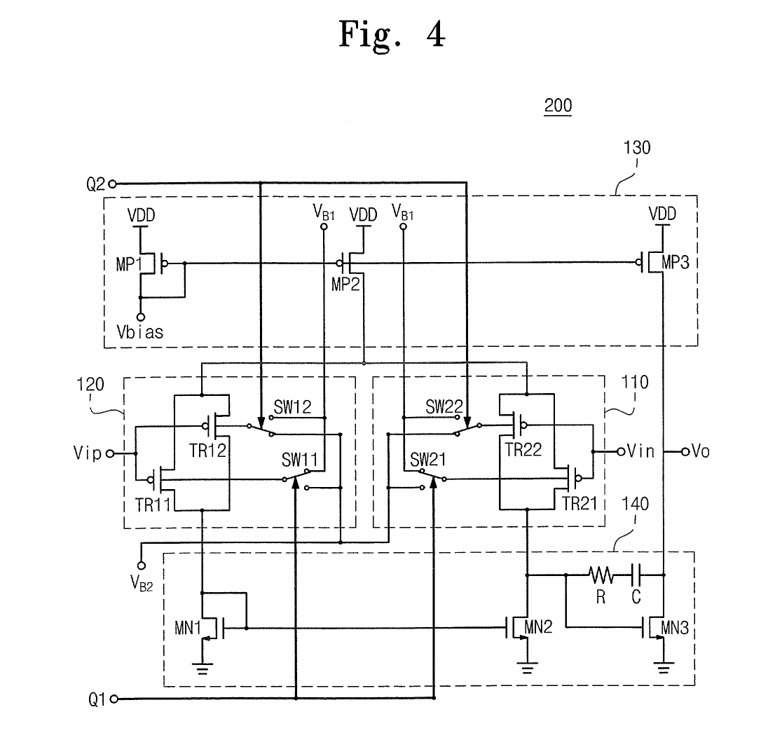

FIG. 4 is a circuit diagram of a CMOS amplifier according to another exemplary embodiment of the present invention. Referring to FIG. 4, a CMOS amplifier 200 includes a first CMOS amplifier 110, a second CMOS amplifier 120, a power supply unit 130, and an output unit 140.

Unlike the CMOS amplifier 100 illustrated in FIG. 1, the first and second CMOS amplifiers 110 and 120 include a first transistor and a second transistor that are implemented using P-channel MOSFETs (P-MOSFETs) instead of N-channel MOSFETs. The power supply unit 130 supplies a supply voltage VDD to source terminals S of the first and second CMOS amplifiers 110 and 120. The power supply unit 130 includes a first power transistor MP1, a second power transistor MP2, and a third power transistor MP3. The supply voltage VDD is connected to the sources of the first, second and third power transistors MP1, MP2 and MP3, and a bias voltage Vbias is connected to the gates thereof. The source terminals of the first and second CMOS amplifiers 110 and 120 are connected to the drain of the second power transistor MP2, and an output terminal Vo is connected to the drain of the third power transistor MP3.

The output unit 140 includes a first transistor MN1, a second transistor MN2, a third transistor MN3, a resistor R, and a capacitor C. The source of the first transistor MN1 is connected to the drain terminal of the first CMOS amplifier 110, and the source of the second transistor MN2 is connected to the drain terminal of the second CMOS amplifier 120. The gates of the first and second transistors MN1 and MN2 are connected to the drain terminal of the second CMOS amplifier 120. The gate of the third transistor MN3 is connected to the drain terminal of the first CMOS amplifier 110, and the gate of the third transistor MN3 is connected to the output terminal Vo. The drains of the first, second and third transistors MN1, MN2 and MN3 are connected to a ground voltage VSS. Also, the resistor R and the capacitor C are connected in series between the output terminal Vo and the source of the second transistor MN2.

The output unit 140 outputs an output signal to the output terminal Vo in proportion to the currents flowing from the drain terminals of the first and second CMOS amplifiers 110 and 120. The resistor R and the capacitor C in the output unit 140 attenuate a high-frequency component (e.g., a glitch) contained in the output signal. A normal input signal is applied to a first input terminal Vip, and an inverted input signal of the normal input signal is applied to a second input terminal Vin.

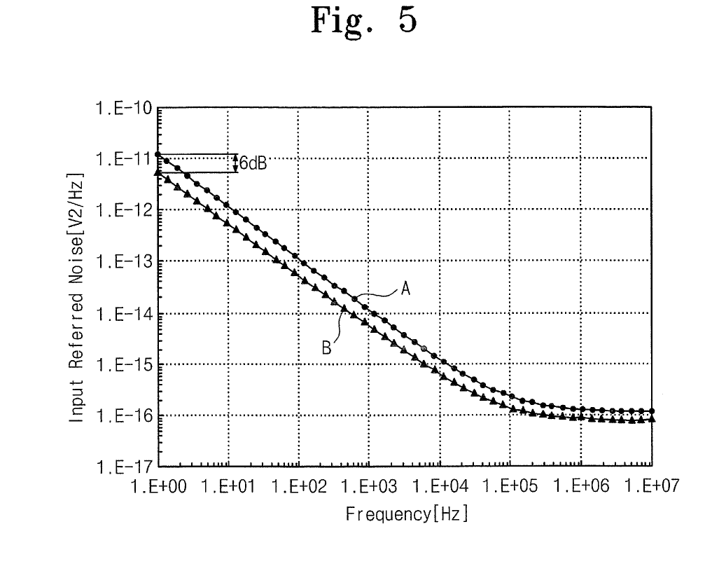

FIG. 5 is a frequency versus noise graph of the CMOS amplifier illustrated in FIG. 4. Referring to FIG. 5, a right upward curve A is a frequency versus noise curve in case of a direct current (DC), and a left downward curve B is a frequency versus noise curve in case that a 1-MHz clock is applied to the CMOS amplifier according to the illustrated embodiment. It can be seen from FIG. 5 that about a 6-dB noise reduction effect may be achieved in comparison with the case of the direct current.

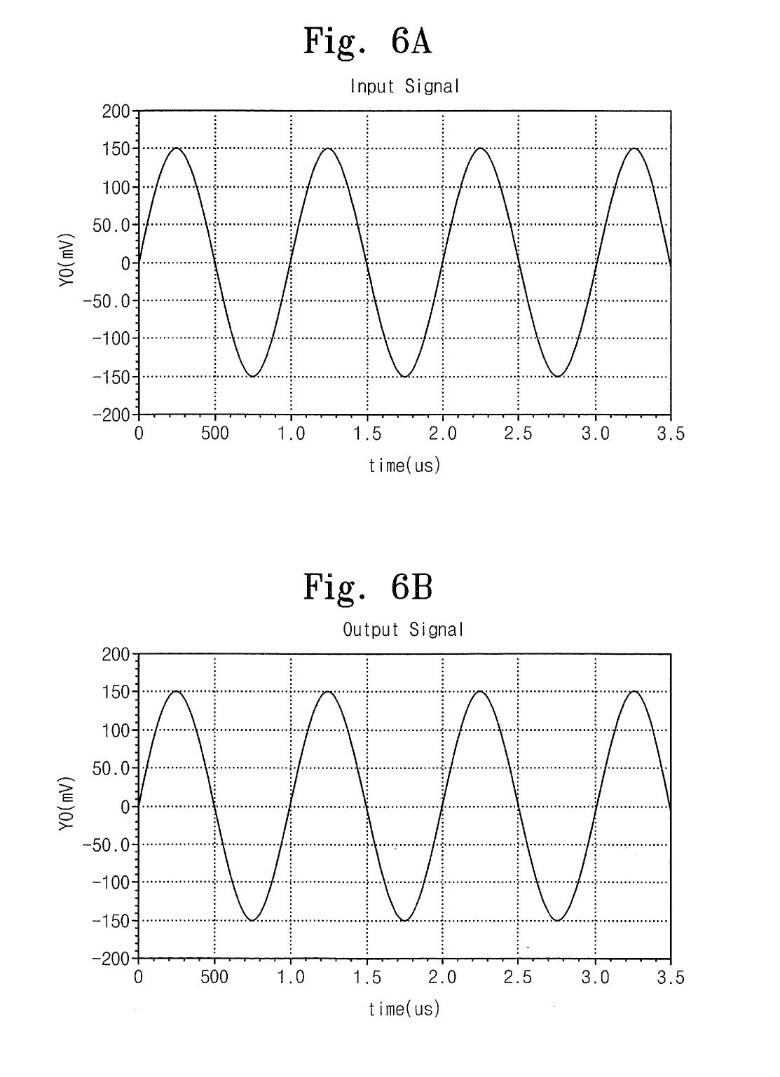

FIGS. 6A and 6B are graphs showing an input signal and an output signal of the CMOS amplifier illustrated in FIG. 4. The CMOS amplifier according to the illustrated embodiment receives an input signal shown in FIG. 6A, and outputs an output signal shown in FIG. 6B. In the present invention, two transistors are alternately driven in synchronization with two complementary clocks. Thus, the present invention can process an input signal all the time. That is, the present invention can be applied to continuous signal processing.

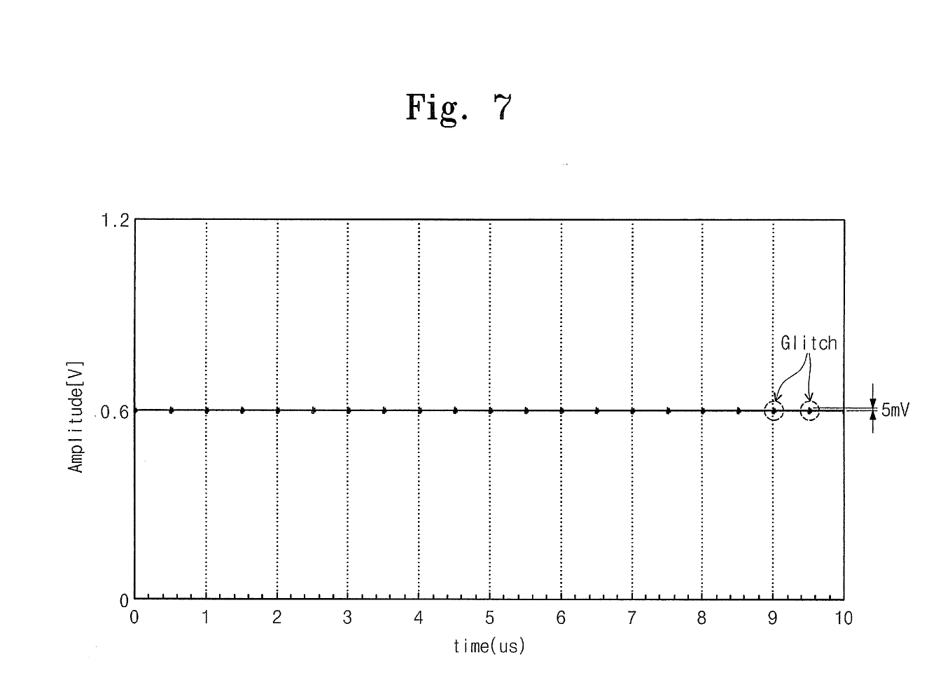

FIG. 7 is a time versus amplitude graph of the CMOS amplifier illustrated in FIG. 4. Referring to FIG. 7, the CMOS amplifier exhibits a constant amplitude all the time. Also, glitches are generated at regular intervals because the first and second transistors of the present invention are driven alternately. Simulating the CMOS amplifier 200 of FIG. 4 results in a glitch of about 5 mV. The simulation according to the present invention is performed using a SpectreRF (RF simulator) of Cadence, Inc. Such a level of glitch does not significantly affect the sensitivity of a communication system and can be attenuated by a low-pass filter (LPF) if necessary.

Thus, as described above with respect to FIGS. 1-2, an integrated circuit device 100 may include a pair of field effect transistors (TR1, TR2) having shared source terminals, shared drain terminals and shared gate terminals. A switch circuit (SW1, SW2) is also provided. The switch circuit is configured to drive a body terminal of a first one (TR1) of the pair of field effect transistors with an alternating sequence of first and second unequal body voltages (e.g., VB1, VB2). This alternating sequence is synchronized with a first clock signal (Q1). The switch circuit is also configured to drive a body terminal of a second one (TR2) of the pair of field effect transistors with an alternating sequence of third and fourth unequal body voltages (e.g., VB1, VB2), which is synchronized with a second clock signal (Q2). As illustrated, the first and third body voltages may have equivalent magnitudes and the second and fourth body voltages may have equivalent magnitudes. In addition, the first and second clock signals (Q1, Q2) may be synchronized with each other. The first and second clock signals may have equivalent duty cycles. In particular, the first and second clock signals may have 50% duty cycles and may be 180 degrees out-of-phase relative to each other. Alternatively, based on the configuration of the switches SW1 and SW2, the first and second clock signals may be the same clock signal. In particular, the first switch SW1 may be configured to be closed and the second switch SW2 may be configured to be open when the clock signal is logic 1. Alternatively, the first switch SW1 may be configured to be open and the second switch SW2 may be configured to be closed when the clock signal is logic 0.

As illustrated by FIG. 4, a differential amplifier 200 may be provided with first and second pairs of field effect transistors and first and second switch circuits. (See, e.g., 110, 120). The first pair of field effect transistors TR21, TR22 have shared first source terminals, shared first drain terminals and shared first gate terminals. The shared first gate terminals are electrically connected to a first input (Vin) of the differential amplifier 200. The shared second pair of field effect transistors TR11, TR12 have shared second source terminals, shared second drain terminals and shared second gate terminals. The shared second gate terminals are electrically connected to a second input Vip of the differential amplifier 200. The first switch circuit SW21, SW22 is configured to drive a body terminal of a first one of the first pair of field effect transistors with an alternating sequence of first and second unequal body voltages that is synchronized with a first clock signal. This first switch circuit may also be configured drive a body terminal of a second one of the first pair of field effect transistors with an alternating sequence of third and fourth unequal body voltages that is synchronized with a second clock signal. Similarly, the second switch circuit SW11, SW12 is configured to drive a body terminal of a first one of the second pair of field effect transistors with the alternating sequence of the first and second unequal body voltages, and may be further configured to drive a body terminal of a second one of the second pair of field effect transistors with the alternating sequence of third and fourth unequal body voltages.

The differential amplifier 200 may also include an output circuit 140, which is electrically coupled to the shared first drain terminals and the shared second drain terminals, and a current mirror circuit 130, which is electrically coupled to the shared first source terminals and the shared second source terminals.

In the drawings and specification, there have been disclosed typical preferred embodiments of the invention and, although specific terms are employed, they are used in a generic and descriptive sense only and not for purposes of limitation, the scope of the invention being set forth in the following claims.

1. An integrated circuit device, comprising:
a pair of field effect transistors having shared source terminals, shared drain terminals and shared gate terminals; and
a switch circuit configured to drive a body terminal of a first one of said pair of field effect transistors with an alternating sequence of first and second unequal body voltages that is synchronized with a first clock signal.

2. The device of claim 1, wherein said switch circuit is further configured to drive a body terminal of a second one of said pair of field effect transistors with an alternating sequence of third and fourth unequal body voltages that is synchronized with a second clock signal.

3. The device of claim 2, wherein the first and second clock signals are synchronized with each other.

4. The device of claim 3, wherein the first and second clock signals have 50% duty cycles; and wherein the first and second clock signals are 180 degrees out-of-phase relative to each other.

5. The device of claim 3, wherein the first and second clock signals have equivalent duty cycles; and wherein the first and second clock signals are complementary versions of each other.

6. The device of claim 2, wherein the first and second clock signals are equivalent clock signals.

7. The device of claim 2, wherein the first and third body voltages have equivalent magnitudes and the second and fourth body voltages have equivalent magnitudes.

8. A differential amplifier, comprising:
a first pair of field effect transistors having shared first source terminals, shared first drain terminals and shared first gate terminals, said shared first gate terminals electrically connected to a first input of the differential amplifier;
a second pair of field effect transistors having shared second source terminals, shared second drain terminals and shared second gate terminals, said shared second gate terminals electrically connected to a second input of the differential amplifier;
a first switch circuit configured to drive a body terminal of a first one of said first pair of field effect transistors with an alternating sequence of first and second unequal body voltages that is synchronized with a first clock signal; and
a second switch circuit configured to drive a body terminal of a first one of said second pair of field effect transistors with the alternating sequence of the first and second unequal body voltages.

9. The differential amplifier of claim 8, further comprising:
an output circuit electrically coupled to the shared first drain terminals and the shared second drain terminals.

10. The differential amplifier of claim 9, further comprising:
a current mirror circuit electrically coupled to the shared first source terminals and the shared second source terminals.

11. The differential amplifier of claim 8, further comprising:
a current mirror circuit electrically coupled to the shared first source terminals and the shared second source terminals.

12. The device of claim 8, wherein said first switch circuit is further configured to drive a body terminal of a second one of said first pair of field effect transistors with an alternating sequence of third and fourth unequal body voltages that is synchronized with a second clock signal.

13. The device of claim 12, wherein said second switch circuit is further configured to drive a body terminal of a second one of said second pair of field effect transistors with the alternating sequence of third and fourth unequal body voltages.

14. The device of claim 13, wherein the first and second clock signals are complementary versions of each other.

15. A complementary metal oxide semiconductor (CMOS) amplifier comprising:
first and second transistors; and
a switch circuit alternately applying first and second body voltages to first and second transistors in response to first and second clocks such that the first and second transistors are variable.

16. The CMOS amplifier of claim 15, wherein the first and second transistors are alternately driven by the operation of the switch circuit.

17. The CMOS amplifier of claim 15, wherein the first and second transistors comprise:
a source terminal connecting the sources of the first and second transistors in common;
a gate terminal connecting the gates of the first and second transistors in common; and
a drain terminal connecting the drains of the first and second transistors in common.

18. The CMOS amplifier of claim 17, wherein the source terminal receives a supply voltage, the gate terminal receives an external signal, and the drain terminal is an output terminal.

19. The CMOS amplifier of claim 15, wherein the first and second clocks have a duty cycle of 50% and are complementary to each other.

20. The CMOS amplifier of claim 15, wherein the first and second transistors are one of an n-type field-effect transistor (FET) and a p-type FET.

21. The CMOS amplifier of claim 15, wherein the switch circuit comprises metal oxide semiconductor (MOS) switches.

22. A complementary metal oxide semiconductor (CMOS) amplifier comprising:
a first transistor comprising a first source, a first gate, a first drain, and a first body;
a second transistor comprising a second source, a second gate, a second drain, and a second body;
a source terminal connecting the first source and the second source in common;
a drain terminal connecting the first drain and the second drain in common;
a gate terminal connecting the first gate and the second gate in common;
a first switch connecting one of a first body voltage and a second body voltage to the first body according to a first clock; and
a second switch connecting one of the first body voltage and the second body voltage to the second body according to a second clock.

23. The CMOS amplifier of claim 22, wherein the source terminal receives a supply voltage, the gate terminal receives an external signal, and the drain terminal is an output terminal.

24. The CMOS amplifier of claim 22, wherein the first transistor has a first threshold voltage if the first body voltage is connected to the first body; and the first transistor has a second threshold voltage if the second body voltage is connected to the first body.

25. The CMOS amplifier of claim 22, wherein the second transistor has a first threshold voltage if the first body voltage is connected to the second body; and the second transistor has a second threshold voltage if the second body voltage is connected to the second body.

26. The CMOS amplifier of claim 22, wherein the voltage applied to the gate terminal is between the first threshold voltage and the second threshold voltage.

27. The CMOS amplifier of claim 22, wherein the first clock is an inversion of the second clock.

28. The CMOS amplifier of claim 22, wherein while the first clock is in a high state, the first switch connects the first body to the first body voltage and the second switch connects the second body to the second body voltage.

29. The CMOS amplifier of claim 22, wherein while the first clock is in a low state, the first switch connects the first body to the second body voltage and the second switch connects the second body to the first body voltage.

30. The CMOS amplifier of claim 22, wherein the first and second transistors are field-effect transistors (FETs).

31. The CMOS amplifier of claim 22, wherein the first and second transistors are one of an n-type transistor and a p-type transistor.

32. The CMOS amplifier of claim 22, wherein the first switch and the second switch are metal oxide semiconductor (MOS) switches.
